(19) United States
(12) Patent Application Publication
(10) Pub. No.: US 2026/0323982 A1
(43) Pub. Date: Oct. 15, 2026

(54) HEMT DEVICE AND MANUFACTURING METHOD THEREOF

(71) Applicant: Silergy Semiconductor Technology (Hangzhou) LTD, Hangzhou (CN)

(72) Inventors: Li Zhang, Hangzhou (CN); Qiyue Zhao, Hangzhou (CN); Pengxiang Bai, Hangzhou (CN); Xiao Wang, Hangzhou (CN)

(21) Appl. No.: 19/639,788

(22) Filed: Apr. 6, 2026

(30) Foreign Application Priority Data
Apr. 15, 2025 (CN) 202510472187.3

(51) Int. Cl. H10D 30/47; H10D 30/01; H10D 62/13; H10D 84/01; H10D 84/83

(52) U.S. Cl. CPC H10D 30/475; H10D 30/015; H10D 62/151; H10D 84/013; H10D 84/0135; H10D 84/83138

(57) ABSTRACT

A method of making an HEMT device can include: forming a base layer and a channel layer located on the base layer; forming a barrier layer structure on an upper surface of the channel layer by a single-step or a multi-step process, where the barrier layer structure comprises a first region and a second region arranged spaced apart; implanting ions into the first region of the barrier layer structure to form an n-type doped ion layer; forming a gate structure on the second region of the barrier layer structure; forming a source metal and a drain metal on the first region of the barrier layer structure; where the ion layer is activated by a growth temperature during the formation of the III-V compound in the gate structure and/or in the second region of the barrier layer structure, to reduce ohmic contact resistance of the source and drain metals.

### RELATED APPLICATIONS

This application claims the benefit of Chinese Patent Application No. 202510472187.3, filed on April 15, 2025, which is incorporated herein by reference in its entirety.

### FIELD OF THE INVENTION

The present invention generally relates to the field of semiconductors, and more particularly, to HEMT devices and methods of manufacturing HEMT devices.

### BACKGROUND

As the market demands higher volume and efficiency requirements for power devices, wide bandgap semiconductor GaN devices have been widely used in high-frequency power conversion systems due to their lower power loss and faster switching capability. As compared with silicon metal-oxide-semiconductor field-effect transistors (MOSFETs), GaN high-electron-mobility transistors (HEMTs) have better figure of merit and more promising performance in high-power and high-frequency applications. To further enhance the performance of GaN transistors, reducing the on-resistance of the device can be utilized, whereby the reduction of ohmic contact (source metal and drain contact) resistance is particularly critical.

### BRIEF DESCRIPTION OF THE DRAWINGS

FIG. 1 is a flow diagram of an example method of making an HEMT device, in accordance with embodiments of the present invention.

FIGS. 2A-2H are structural diagrams of various steps in a first example method of making an HEMT device, in accordance with embodiments of the present invention.

FIGS. 3A-3B are structural diagrams of various steps in a second example method of making an HEMT device, in accordance with embodiments of the present invention.

FIGS. 4A-4E are structural diagrams of various steps in a third example method of making an HEMT device, in accordance with embodiments of the present invention.

FIG. 5 is a flow diagram of an example method of making an HEMT device including a depletion-mode structure and an enhancement-mode structure, in accordance with embodiments of the present invention.

FIGS. 6A-6G are structural diagrams of various steps in a fourth example method of making an HEMT device, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Further, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

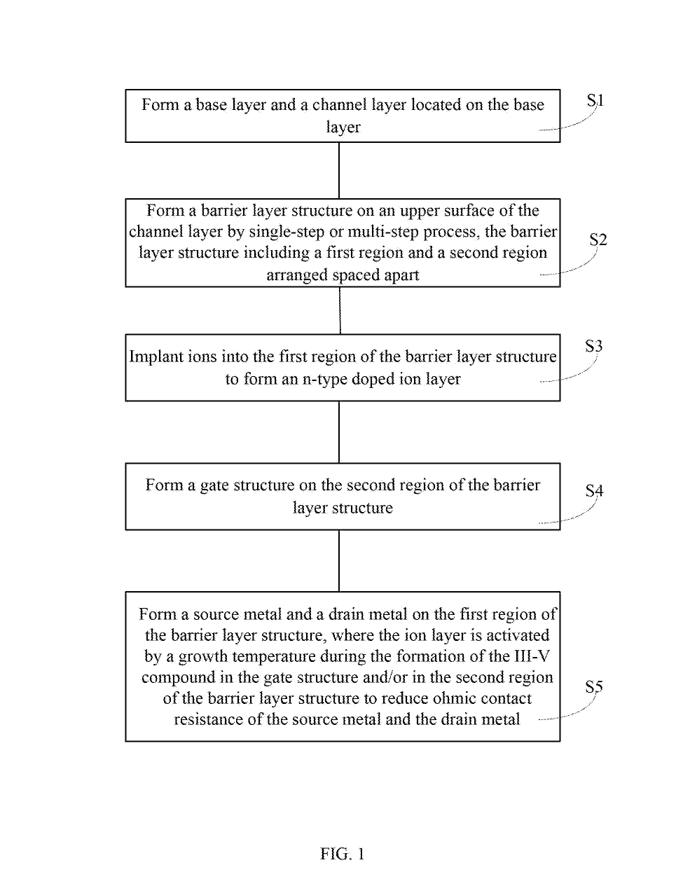

Referring now to FIG. 1, shown is a flow diagram of an example method of making an HEMT device, in accordance with embodiments of the present invention. In this particular example, a method of making an HEMT device can include, at S1, forming a base layer and a channel layer on the base layer. At S2, the method can also include forming a barrier layer structure on an upper surface of the channel layer by single-step or multi-step process, where the barrier layer structure can include a first region and a second region arranged spaced apart. At S3, the method can also include implanting ions into the first region of the barrier layer structure to form an n-type doped ion layer. At S4, the method can also include forming a gate structure on the second region of the barrier layer structure. At S5, the method can also include forming a source metal and a drain metal on the first region of the barrier layer structure, where the ion layer is activated by a growth temperature during the formation of the gate structure and/or the III-V compound (such as GaN, AlGaN, AlN, etc.) in the second region of the barrier layer structure, in order to reduce the ohmic contact resistance of the source metal and drain metal.

In one embodiment, the method of forming the barrier layer structure can include forming a first barrier layer covering the upper surface of the channel layer. For example, the gate structure may be located on the second region of the first barrier layer. In another embodiment, the barrier layer structure can include a first barrier layer located at least in the first region, and a second barrier layer located at least in the second region, where a thickness of the second barrier layer may be less than a thickness of the first barrier layer. Forming the barrier layer structure can include forming a first barrier layer covering the upper surface of the channel layer, etching a portion of the first barrier layer to expose a portion of the upper surface of the channel layer, and regrowing a second barrier layer on the exposed channel layer, where the second barrier layer can include a III-V compound-based material (e.g., AlN, GaN, AlGaN, etc.) and the gate structure can be located on the second barrier layer.

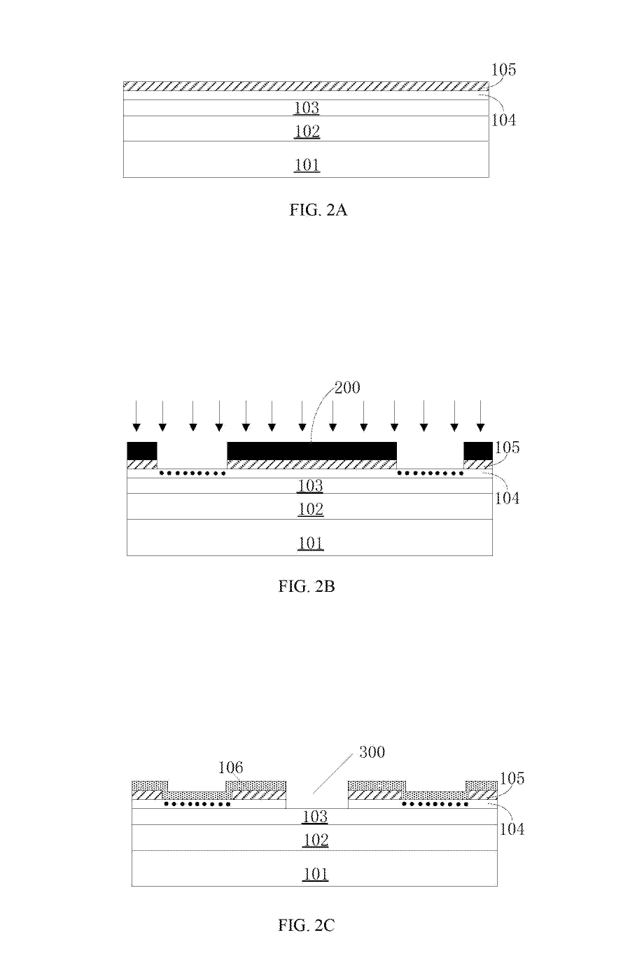

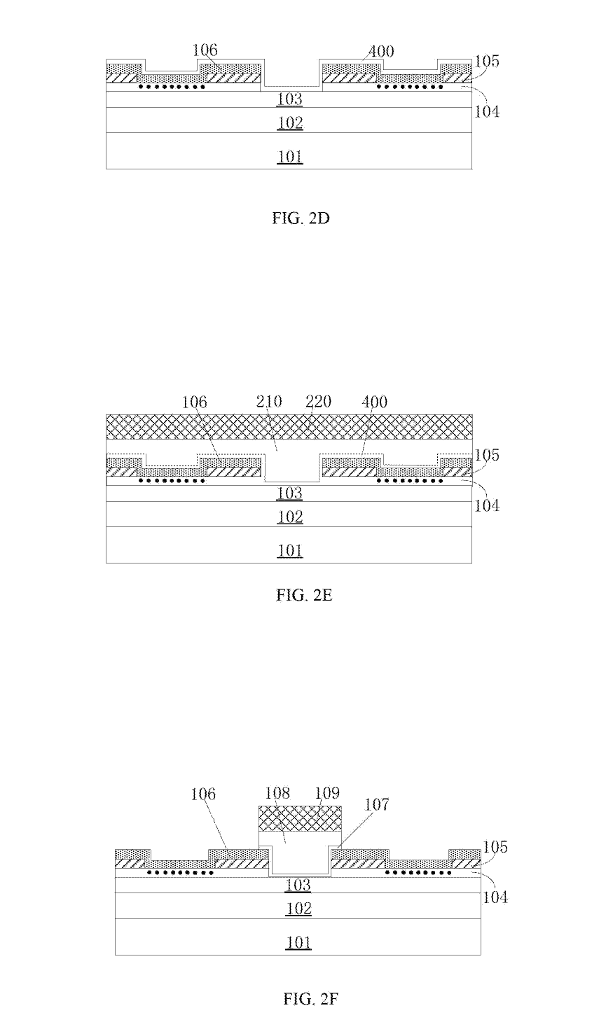

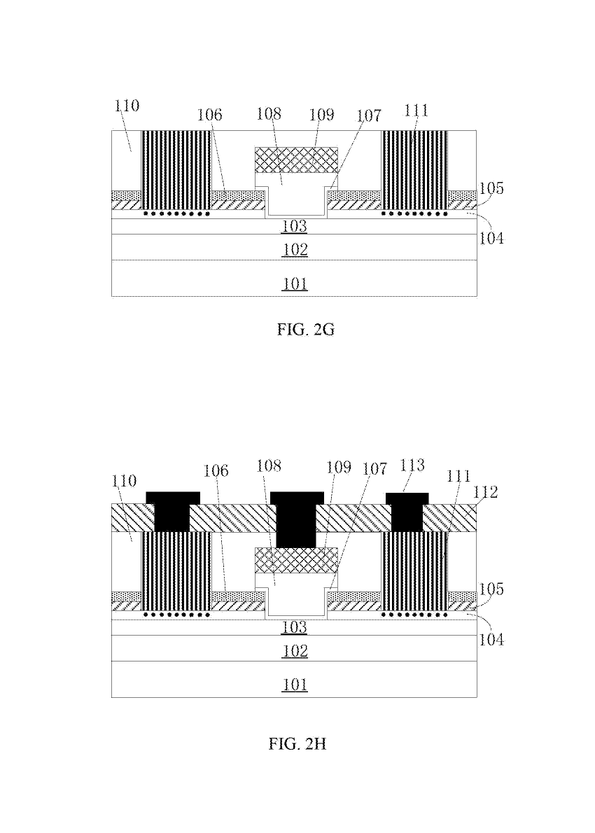

Referring now to FIGS. 2A-2H, shown are structural diagrams of various steps in a first example method of making an HEMT device, in accordance with embodiments of the present invention. In this particular example, the HEMT is described as an enhancement-mode structure, and the barrier layer structure can be formed by multi-step process. The barrier layer structure can include a first barrier layer located at least in the first region, and a second barrier layer located at least in the second region, where the thickness of the second barrier layer may be less than the thickness of the first barrier layer.

At S1, a base layer and a channel layer can be formed. As shown in FIG. 2A, the base layer and channel layer 103 on the base layer may be sequentially formed. The base layer may include substrate 101. In one embodiment, the base layer may include substrate 101 and buffer layer 102, and buffer layer 102 can be disposed between substrate 101 and channel layer 103, in order to reduce the problem of lattice mismatch between substrate 101 and channel layer 103. Substrate 101 may be a silicon substrate, a sapphire substrate, a silicon carbide (SiC) substrate, an aluminum nitride (AlN) substrate, or silicon on insulator (SOI), etc., and buffer layer 102 may be a III-V compound (e.g., AlN, GaN, AlGaN, etc.).

At S2, a barrier layer structure can be formed on the upper surface of channel layer 103, where the barrier layer structure can include a first region and a second region arranged spaced apart from each other. For example, the barrier layer structure can include a first barrier layer located at least in the first region, and a second barrier layer located at least in the second region, where the thickness of the second barrier layer may be less than the thickness of the first barrier layer.

As shown in FIG. 2A, barrier layer 104 can be formed on channel layer 103, where channel layer 103 has a (relatively) small bandgap layer (e.g., a GaN semiconductor layer), and barrier layer 104 has a (relatively) large bandgap layer (e.g., an AlGaN, InAlN, AlN, etc. semiconductor layer). A two-dimensional electron gas can be formed at the interface between channel layer 103 and barrier layer 104, e.g., at the top of the channel layer 103. For example, the second barrier layer can be formed in a subsequent process. In one embodiment, capping layer 105 may be located on barrier layer 104, where capping layer 105 can be utilized to protect the surface of barrier layer 104, in order to prevent oxidation of barrier layer 104. Capping layer 105 may include a III-V compound (e.g., GaN, AlGaN, etc.).

At S3, an n-type doped ion layer can be formed by implanting ions into the first region of the barrier layer structure (e.g., barrier layer 104). In the example shown in FIG. 2B, patterned photoresist layer 200 can be formed on capping layer 105, where the patterned photoresist layer 200 may expose a predetermined region of capping layer 105. Further, the exposed capping layer 105 can be etched to expose the first region of barrier layer 104. Finally, ions may be implanted into the first region of barrier layer 104 to form an n-type doped ion layer. For example, the source and drain electrodes may subsequently be formed can be on the first region. The ions may include silicon ions, oxygen ions, germanium ions, nitrogen ions, etc., whereby the silicon ions substitute for gallium ions in the first barrier layer (e.g., AlGaN) to form n-type doping, or the oxygen ions substitute for nitrogen ions in the first barrier layer (e.g., AlGaN) to form n-type doping. Finally, photoresist layer 200 can be removed.

In one embodiment, the HEMT device may not include a capping layer. In this case, the method can include forming a mask layer on the first barrier layer, where the mask layer exposes the upper surface of the first region of the first barrier layer, and then implanting ions into the first region of barrier layer 104 to form an n-type doped ion layer. After forming the n-type doped ions, the method at S2 can be continued to form the second barrier layer in the barrier layer structure.

As shown in FIG. 2C, dielectric layer 106 can be formed on capping layer 105 and exposed first barrier layer (e.g., the step of forming the dielectric layer 106 may also be omitted) to protect capping layer 105. Then, a portion of dielectric layer 106, a portion of capping layer 105, and a portion of barrier layer 104 may be etched to expose a portion of the upper surface of channel layer 103. The exposed region of channel layer 103 may be set as gate region 300, and gate region 300 can be spaced apart from the first region.

As shown in FIG. 2D, a barrier layer 400 can be formed on the upper surface of the structure shown in FIG. 2C, e.g., barrier layer 400 may cover dielectric layer 106 and the exposed upper surface of channel layer 103, and barrier layer 400 can include a III-V compound material. In this example, barrier layer 400 may include AlGaN material. In addition, the thickness of the second barrier layer may be less than the thickness of the first barrier layer, making it easier to form an enhancement-mode high electron mobility transistor. Also, the growth temperature (e.g., growth temperature greater than 1000 degrees C) during the regrowth of the second barrier layer can effectively activate the ion layer. At S4, a gate structure may be formed on the second region of the barrier layer structure.

As shown in FIG. 2E, P-type gate 210 may continue to grow on barrier layer 400 and form gate metal 220 on P-type gate 210, where P-type gate 210 may be P-type GaN or P-type AlGaN. For example, the growth temperature for growing the P-type GaN or P-type AlGaN 210 can be greater than 1000 degrees C, which can further activate the ion layer. The gate metal can be formed by a deposition process, and the metal may include titanium, nickel, titanium nitride, gold, etc. As shown in FIG. 2F, a portion of gate metal 220, a portion of the P-type gate 210, and a portion of barrier layer 400 may sequentially be etched to form a gate structure and barrier layer 107. For example, the gate structure can include P-type gate 108 covering the upper surface of barrier layer 107, and gate metal 109 covering the upper surface of the P-type gate 108.

At S5, source metal and drain metal 111 may be formed on the first region. For example, as shown in FIG. 2G, interlayer dielectric layer 110 may be formed covering the upper surfaces of dielectric layer 106 and gate metal 109. Then, a portion of interlayer dielectric layer 110 and dielectric layer 106 can be etched to expose the first region of barrier layer 104, and form source metal and drain metal 111 in the first region. Since the first region of the first barrier layer may have been doped with n-type by ion implantation, and the ion layer can be activated by the growth temperature during the growth of the III-V compound material, the ohmic contact resistance of the source metal and drain metal can accordingly be reduced.

As shown in FIG. 2H, a passivation layer 112 may be formed covering the upper surfaces of interlayer dielectric layer 110, and source metal and drain metal 111. Here, the method can also include forming a first opening passing through passivation layer 112 and exposing a portion of the upper surface of source metal and drain metal 111, and forming a second opening starting from the upper surface of passivation layer 112, passing through the passivation layer and a portion of interlayer dielectric layer 110, and exposing the upper surface of gate metal 109. Interconnect metal layer 113 can be formed in the first opening and the second opening, respectively.

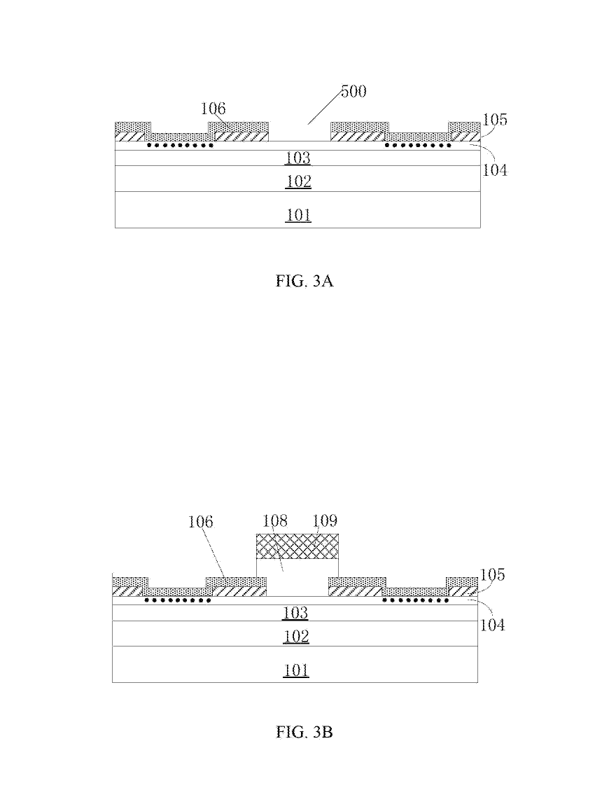

Referring now to FIGS. 3A-3B, shown are structural diagrams of various steps in a second example method of making an HEMT device, in accordance with embodiments of the present invention. In this particular example, the HEMT is described as an enhancement-mode structure, and the barrier layer structure can be formed in single-step process, without regrowing the second barrier layer, e.g., S2 can include a different specific method. For example, S2 can include forming barrier layer 104 on channel layer 103 to form the barrier layer structure, and after forming the n-type doped ions in the first region of the first barrier layer, barrier layer 104 may not be etched to expose channel layer 103.

For example, as shown in FIG. 3A, dielectric layer 106 can be formed on capping layer 105 and the exposed first barrier layer to protect the capping layer 105. Then, a portion of the dielectric layer 106 and a portion of the capping layer 105 may be etched to expose a portion of the upper surface of barrier layer 104, where the exposed region of barrier layer 104 is set as gate region 500, and gate region 500 can be spaced apart from the first region.

As shown in FIG. 3B, a P-type gate and a gate metal may be formed in the gate region. For example, a P-type gate can be grown on barrier layer 104 and dielectric layer 106, and a gate metal can be formed on the P-type gate. For example, the growth temperature for growing the P-type gate can be greater than 1000 degrees C, which can effectively activate the ion layer. The gate metal may be formed by a deposition process, and the gate metal may include titanium, nickel, titanium nitride, gold, etc. In addition, a portion of the gate metal and a portion of the P-type gate may sequentially be etched to form a gate structure that includes P-type gate 108 covering the upper surface of the exposed first barrier layer, and gate metal 109 covering the upper surface of P-type gate108. For example, P-type gate 210 may be P-type GaN or P-type AlGaN. Particular embodiments may save the step of regrowing the second barrier layer, and while achieving the same effect of activating the ion layer, can accordingly reduce process steps and save process costs.

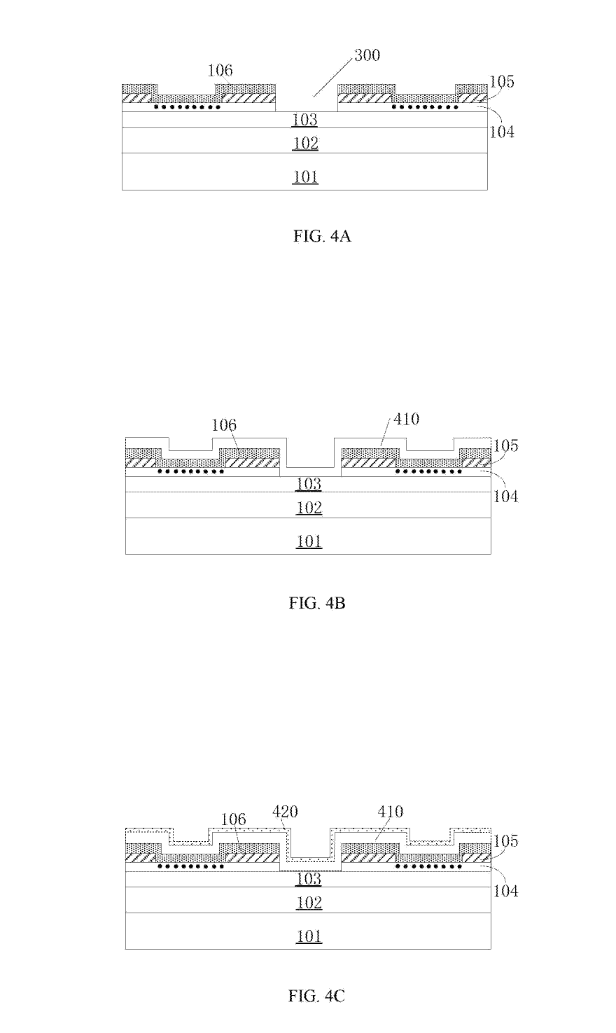

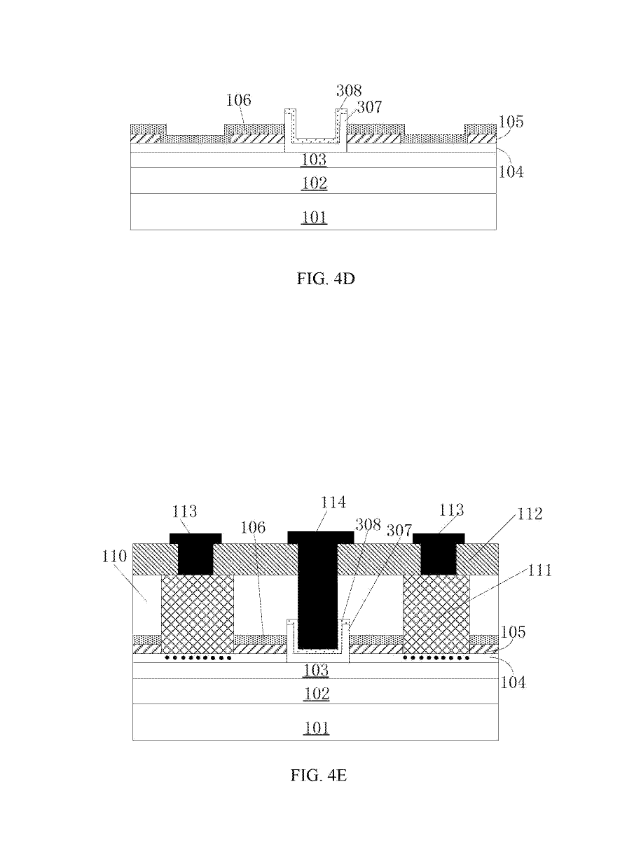

Referring now to FIGS. 4A-4E, shown are structural diagrams of various steps in a third example method of making an HEMT device, in accordance with embodiments of the present invention. In this particular example, the HEMT is described as a depletion-mode structure, and the specific method included in step S4 is different from the example discussed above.

As shown in FIG. 4A, dielectric layer 106 can be formed on capping layer 105 and the exposed first barrier layer to protect capping layer 105. Then, a portion of dielectric layer 106, a portion of capping layer 105, and a portion of barrier layer 104 may be etched to expose a portion of the upper surface of channel layer 103, where the exposed region of the channel layer 103 is set as gate region 300, and gate region 300 can be spaced apart from the first region. Finally, barrier layer 410 can be formed on the upper surface of the structure in FIG. 4A. For example, barrier layer 410 may cover dielectric layer 106 and the exposed upper surface of channel layer 103, as shown in FIG. 4B, where barrier layer 410 can include III-V materials (e.g., AlGaN, AlN, InAlN, etc.). The growth temperature (e.g., growth temperature greater than 1000 degrees C) during the regrowth of barrier layer 410 can effectively activate the ion layer.

As shown in FIG. 4C, gate dielectric layer 420 can continue to be formed on barrier layer 410, and gate dielectric layer 420 may cover the upper surface of second barrier layer 410. For example, gate dielectric layer 420 can include silicon oxide, silicon nitride, etc. Further, as shown in FIG. 4D, a portion of gate dielectric layer 420 and a portion of second barrier layer 410 may sequentially be etched to form barrier layer 307 and gate dielectric layer 308 retained in gate region 300.

At S5 source metal and drain metal 111 may be formed on the first region. For example, as shown in FIG. 4E, interlayer dielectric layer 110 can be formed covering the upper surfaces of dielectric layer 106 and gate dielectric layer 308. Then, a portion of interlayer dielectric layer 110 and dielectric layer 106 can be etched to expose the first region of barrier layer 104, and form source metal and drain metal 111 on the first region of barrier layer 104.

Passivation layer 112 may also be formed covering upper surfaces of interlayer dielectric layer 110, source metal and drain metal 111. This can include a first opening passing through passivation layer 112 and exposing a portion of the upper surface of source metal and drain metal 111, and a second opening starting from the upper surface of passivation layer 112, passing through passivation layer 112 and a portion of interlayer dielectric layer 110, and exposing the upper surface of gate dielectric layer 308. The method can also include forming interconnect metal layer 113 in the first opening and forming gate electrode 114 in the second opening, respectively.

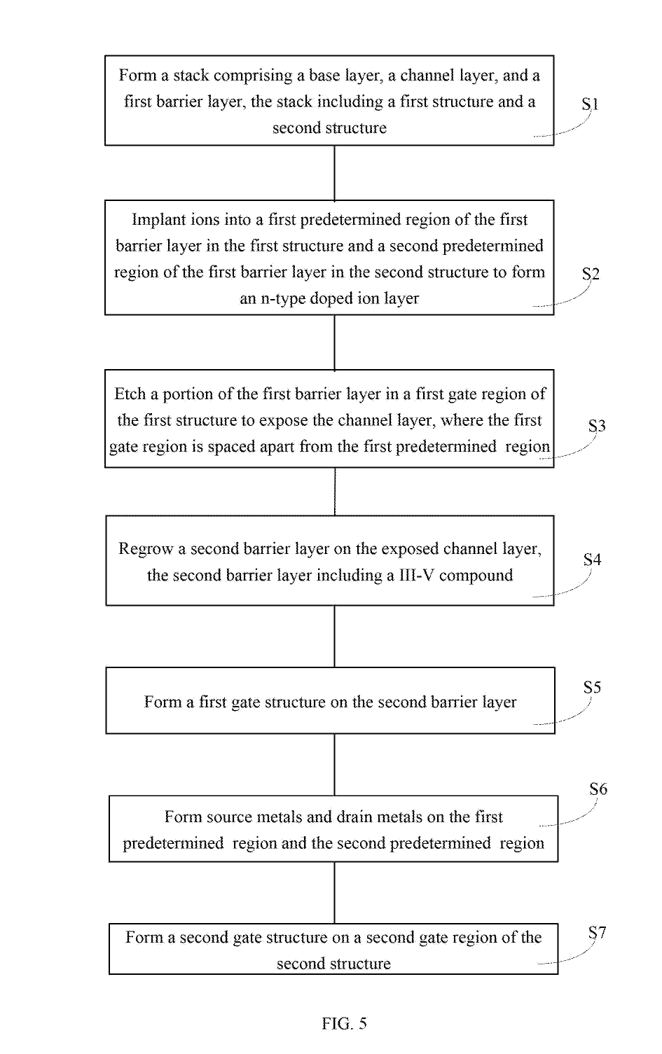

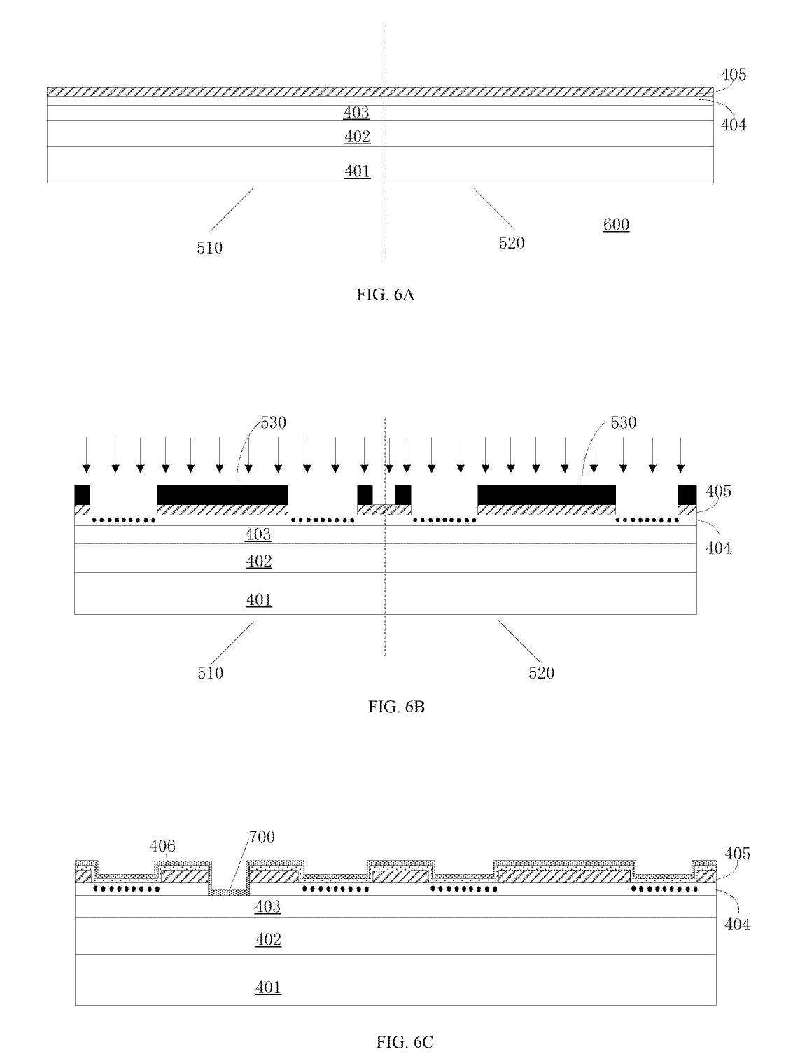

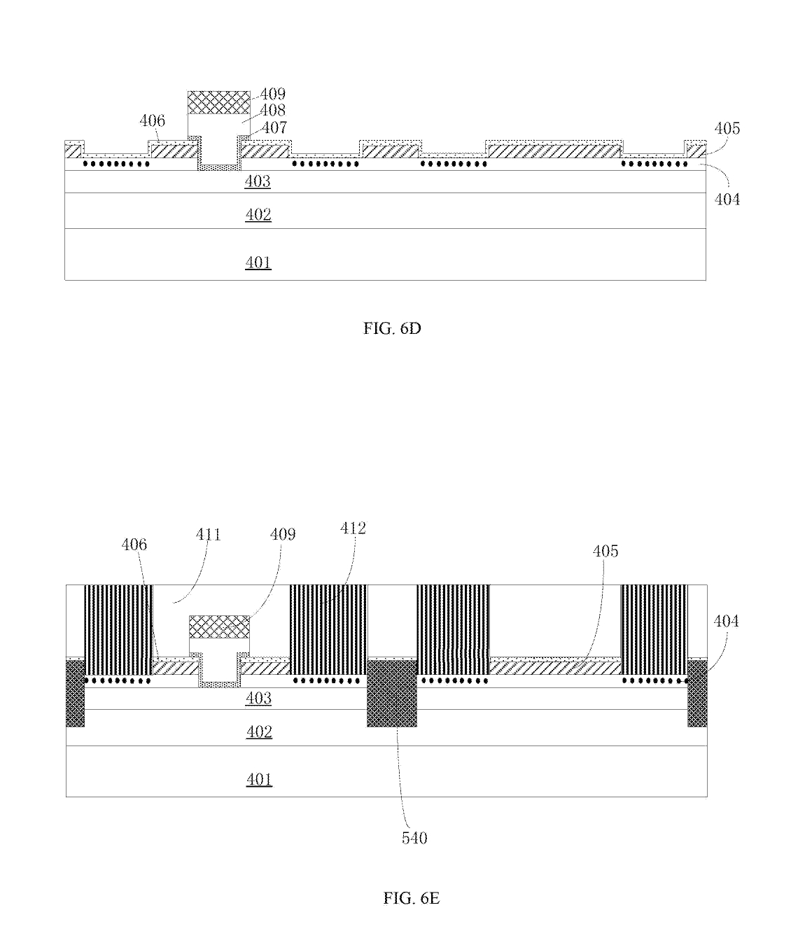

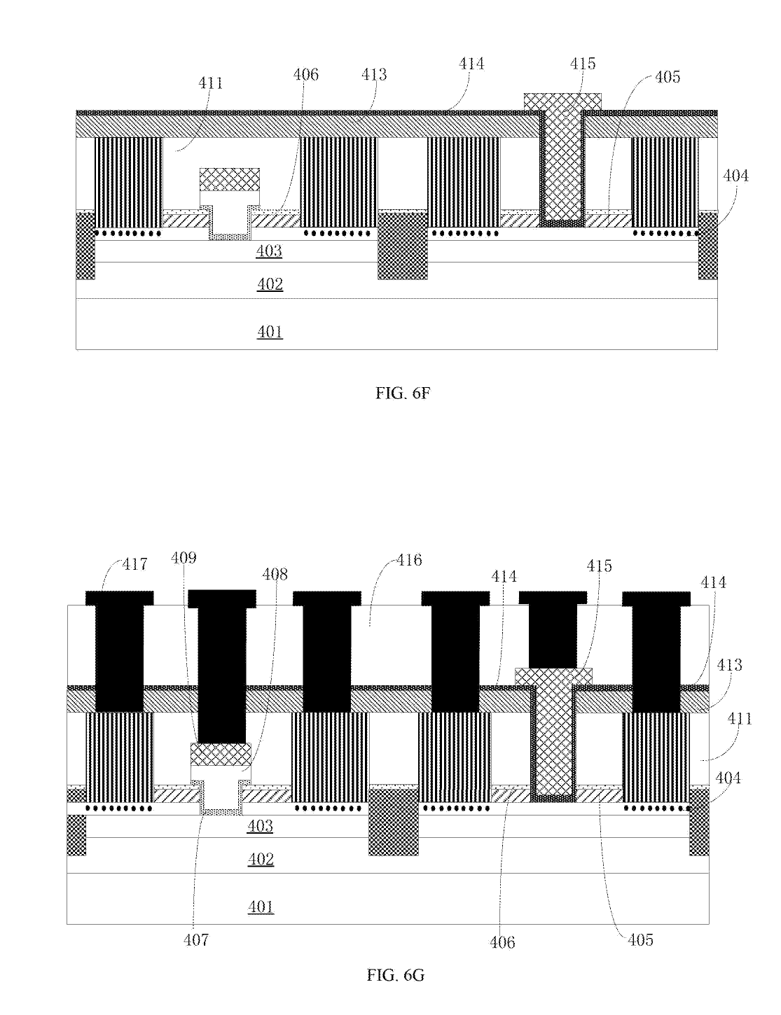

Referring now to FIG. 5, shown is a flow diagram of an example method of making an HEMT device including a depletion-mode structure and an enhancement-mode structure, in accordance with embodiments of the present invention. Referring also to FIGS. 6A-6G, shown are structural diagrams of various steps in a fourth example method of making an HEMT device, in accordance with embodiments of the present invention. In this particular example, the HEMT including an enhancement-mode and a depletion-mode structure is described, and the ion layers in the enhancement-mode and depletion-mode structures are activated by the thermal process of regrowing the second barrier layer of the enhancement-mode structure. At S1, a stack including a base layer, a channel layer, and a first barrier layer, can be formed, where the stack includes a first structure and a second structure.

As shown in FIG. 6A, a base layer, channel layer 403 on the base layer, and barrier layer 404 on channel layer 403 may sequentially be grown to form stack 600. Channel layer 403 may have a (relatively) small bandgap layer (e.g., a GaN semiconductor layer), and barrier layer 404 may have a (relatively) large bandgap layer (e.g., an AlGaN semiconductor layer). A two-dimensional electron gas can be formed at the interface between channel layer 403 and barrier layer 404, e.g., at the top of the channel layer 403. The base layer can include substrate 401. In one embodiment, the base layer can include substrate 401 and buffer layer 402. Buffer layer 402 can be disposed between substrate 401 and channel layer 403 to reduce the degree of lattice mismatch between substrate 401 and channel layer 403. Substrate 401 may be a silicon substrate, a sapphire substrate, a silicon carbide (SiC) substrate, an aluminum nitride (AlN) substrate, or silicon on insulator (SOI), etc., and buffer layer 402 may be a III-V compound (e.g., AlN, GaN, AlGaN, etc.).

In one embodiment, the method may also include forming capping layer 405 located on barrier layer 404, where capping layer 405 can protect the surface of barrier layer 404 to prevent oxidation of barrier layer 404. Capping layer 405 may include a III-V compound (e.g., GaN, AlGaN, etc.). The dashed line in FIG. 6A divides stack 600 into structures 510 and structure 520, where an enhancement-mode structure can be formed on structure 510, and a depletion-mode structure can be formed on structure 520. At S2, ions may be implanted into a first predetermined region of the first barrier layer in the first structure and a second predetermined region of the first barrier layer in the second structure to form an n-type doped ion layer.

An n-type doped ion layer can be formed by implanting ions into predetermined regions of barrier layer 404. For example, as shown in FIG. 6B, patterned photoresist layer 530 can be formed on capping layer 405, where patterned photoresist layer 530 exposes a predetermined region of capping layer 405. Further, the exposed capping layer 405 can be etched to expose the predetermined regions of barrier layer 404. Finally, ions may be implanted into the predetermined regions of barrier layer 404 to form an n-type doped ion layer. For example, the predetermined regions can be set as regions for subsequently forming source and drain electrodes. The ions may include silicon ions, oxygen ions, germanium ions, nitrogen ions, etc., where the silicon ions substitute for gallium ions in the first barrier layer to form n-type doping, or the oxygen ions substitute for nitrogen ions in the first barrier layer to form n-type doping. Finally, photoresist layer 530 can be removed. For example, the predetermined region of the first barrier layer in structure 510 can be set as a first predetermined region, and the predetermined region of the first barrier layer in structure 520 can be set as a second predetermined region.

At S3, a portion of the first barrier layer in a first gate region of the first structure may be etched to expose the channel layer, where the first gate region is spaced apart from the first predetermined region. For example, as shown in FIG. 6C, dielectric layer 406 can be formed on capping layer 405 and the exposed barrier layer 404 to protect capping layer 405. Then, a portion of dielectric layer 406, a portion of the capping layer 405, and a portion of the barrier layer 404 in the first structure may be etched to expose a portion of the upper surface of channel layer 403, where the exposed region of channel layer 403 is set as a first gate region, and the first gate region is spaced apart from the first predetermined region.

Here, only a portion of the upper surface of the channel layer in structure 510 may be exposed, e.g., only the gate region on first structure 510 can be formed. At S4, a second barrier layer may be regrown on the exposed channel layer, where the second barrier layer includes a material layer of a III-V compound. Further, barrier layer 700 can be formed on the upper surface of the above structure, e.g., barrier layer 700 can cover dielectric layer 406 and the exposed upper surface of channel layer 403. For example, barrier layer 700 can include a III-V compound (e.g., GaN, AlGaN, AlN, etc.). Setting the thickness of barrier layer 700 to be less than the thickness of barrier layer 404 can facilitate formation of an enhancement-mode high electron mobility transistor; and the growth temperature (e.g., greater than 1000 degrees C) during the regrowth of barrier layer 700 can effectively activate the ion layer.

At S5, a first gate structure may be formed on the second barrier layer. Further, a P-type gate can continue to grow on barrier layer 700, and a gate metal may be formed on P-type gate 800. For example, the P-type gate may include III-V compound, such as a P-type GaN layer, and the growth temperature for growing the P-type GaN layer may be than, e.g., 1000 degrees C, which can further activate the ion layer. For example, the gate metal can be formed by a deposition process, and the gate metal may include nickel, titanium, titanium nitride, gold, etc.

A portion of the gate metal, a portion of the P-type GaN layer, and a portion of the second barrier layer may sequentially be etched to form a first gate structure above the first structure, where the first gate structure includes barrier layer 407 covering the upper surface of channel layer 403, P-type GaN layer 408 covering the upper surface of barrier layer 407, and gate metal 409 covering the upper surface of P-type GaN layer 408, as shown in FIG. 6D. At S6, source metal and drain metal may be formed on the first predetermined region and the second predetermined region.

For example, as shown in FIG. 6E, interlayer dielectric layer 411 can be formed covering the upper surfaces of dielectric layer 406 and gate metal 409. Then, a portion of interlayer dielectric layer 411, a portion of dielectric layer 406, and a portion of capping layer 405 can be etched to expose the predetermined regions of the barrier layer 404. Finally, source metal and drain metal 412 can be formed in the predetermined regions. For example, first source metal and first drain metal may be formed in the first predetermined region, and second source metal and second drain metal may be formed in the second predetermined region.

The method can also include forming isolation layer 540 between the first structure and the second structure, where the isolation layer extends at least from the lower surface of dielectric layer 406 downward to buffer layer 402. Further, the method can also include forming an isolation layer located at the edge of the HEMT device to isolate from other devices. For example, the isolation layer can be formed by ion implantation, or by etching a trench. At S7, a second gate structure may be formed on the second gate region of the second structure.

As shown in FIG. 6F, a gate dielectric layer and a gate metal may be formed on the second gate region of barrier layer 404 of the second structure. For example, passivation layer 413 can be formed on interlayer dielectric layer 411. Then, a portion of passivation layer 413, a portion of interlayer dielectric layer 411, a portion of dielectric layer 406, and a portion of capping layer 405 may sequentially be etched to form a second gate opening to expose the second gate region of barrier layer 404. Gate dielectric layer 414 can continue to be formed on the second gate region and passivation layer 413, where gate dielectric layer 414 may cover the bottom and sidewalls of the second gate opening, and the upper surface of the first passivation layer. Finally, gate metal 415 may be formed to fill the second gate opening including gate dielectric layer 414 (e.g., including silicon oxide, silicon nitride, etc.).

As shown in FIG. 6G, the method can also include forming passivation layer 416 covering the upper surfaces of gate dielectric layer 414 and gate metal 415. This can include forming a first opening passing through passivation layer 416, gate dielectric layer 414, and passivation layer 413 and exposing the upper surfaces of the first and second source-drain metals, forming a second opening passing through passivation layer 416, gate dielectric layer 414, passivation layer 413, and a portion of the interlayer dielectric layer 411 and exposing the upper surface of the first gate metal, and forming a third opening passing through passivation layer 416 and exposing the upper surface of the second gate metal 415. Also, a first interconnect metal layer 417 may be formed in the first opening, the second opening, and the third opening, respectively.

Particular embodiments may provide a method of making an HEMT device with depletion-mode structure and enhancement-mode structure, where the ion layers of the enhancement-mode structure and the depletion-mode structure are activated by the growth temperature during the regrowth of the second barrier layer in the first gate region of the enhancement-mode structure, in order to simultaneously reduce the ohmic contact resistance of the source metal and drain metal in the enhancement-mode structure and the depletion-mode structure.

Particular embodiments can also provide an HEMT device formed according to the above method. The HEMT device can include a base layer, a channel layer located on an upper surface of the base layer, a barrier layer located on an upper surface of the channel layer, a source metal and a drain metal located on predetermined regions of the barrier layer, and a gate structure located on a gate region of the barrier layer, where a surface of the predetermined regions of the barrier layer can be n-type doped.

As shown in FIG. 2H, for the HEMT device formed according to the example method discussed above, the device can include a base layer, channel layer 103 located on an upper surface of the base layer, barrier layer structure located on an upper surface of the channel layer, source metal and drain metal 111 located on predetermined regions of the barrier layer structure, and a gate structure located on a gate region of the barrier layer. For example, a surface of the predetermined regions of the barrier layer structure can be n-type doped. The base layer can include substrate 101 and buffer layer 102, where buffer layer 102 is disposed between substrate 101 and channel layer 103 to reduce the problem of lattice mismatch between substrate 101 and channel layer 103. Further, the barrier layer structure may include barrier layer 104 and barrier layer 107, where barrier layer 104 can be located above channel layer 103 and can include a first opening exposing a portion of the upper surface of channel layer 103, barrier layer 107 can be located in the first opening, and barrier layer 107 may be located in a gate region of the HEMT device. For example, the thickness of barrier layer 107 may be less than the thickness of the barrier layer 104.

As shown in FIG. 3B, the barrier layer structure may include barrier layer 104, which can completely cover the upper surface of channel layer 103, and the gate structure can be located on barrier layer 104. Further, the method can also include capping layer 105 located on barrier layer 104 to prevent oxidation of the first barrier layer. For example, the capping layer can include a second opening having the same width as the first opening and penetrating through to the first opening. The method can also include dielectric layer 106 located on capping layer 105 to protect capping layer 105. For example, the first dielectric layer can include a third opening having the same width as the second opening and penetrating through to the second opening, in order to accommodate the second barrier layer and the gate structure.

The gate structure can include P-type GaN 108 located on barrier layer 107, and gate metal 109 located on the P-type GaN. As shown in FIG. 4E, the gate structure can include gate dielectric layer 308 located on barrier layer 307, and gate metal 114 located on gate dielectric layer 308. The method can also include interlayer dielectric layer 110 covering dielectric layer 106 and gate metal 109, where source metal and drain metal 111 may extend from an upper surface of the interlayer dielectric layer to the upper surface of barrier layer 104. The method can also include forming passivation layer 112 located on interlayer dielectric layer 110 and interconnect metal 113 extending from an upper surface of passivation layer 112 to the upper surface of gate metal 109/gate metal 114 and the upper surface of source metal and drain metal 111.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. A method of making a high-electron-mobility transistor (HEMT) device, the method comprising:
a) forming a base layer and a channel layer located on the base layer;
b) forming a barrier layer structure on an upper surface of the channel layer by a single-step or a multi-step process, wherein the barrier layer structure comprises a first region and a second region arranged spaced apart;
c) implanting ions into the first region of the barrier layer structure to form an n-type doped ion layer;
d) forming a gate structure on the second region of the barrier layer structure;
e) forming a source metal and a drain metal on the first region of the barrier layer structure; and
f) wherein the ion layer is activated by a growth temperature during the formation of the III-V compound in the gate structure and/or in the second region of the barrier layer structure, in order to reduce ohmic contact resistance of the source metal and the drain metal.

2. The method of claim 1, wherein the forming the barrier layer structure by single-step process comprises forming a first barrier layer covering the upper surface of the channel layer to form the barrier layer structure, and wherein the ion layer is activated by the growth temperature during the formation of the III-V compound in the gate structure.

3. The method of claim 1, wherein when the barrier layer structure is formed by the multi-step process, the barrier layer structure comprises a first barrier layer located at least in the first region, and a second barrier layer located at least in the second region, and wherein a thickness of the second barrier layer is less than a thickness of the first barrier layer.

4. The method of claim 2, wherein the forming the gate structure comprises
forming a P-type GaN on the second region of the first barrier layer, and
forming a gate metal on the P-type GaN.

5. The method of claim 3, wherein the forming the barrier layer structure comprises:
a) forming the first barrier layer covering the upper surface of the channel layer;
b) etching a portion of the first barrier layer to expose a portion of the upper surface of the channel layer after forming the n-type doped ion layer in the first region of the first barrier layer; and
c) forming the second barrier layer on the exposed channel layer, wherein the second barrier layer comprises the III-V compound.

6. The method of claim 3, wherein the forming the gate structure comprises forming a P-type GaN on the second barrier layer, and forming a gate metal on the P-type GaN, wherein the ion layer is activated by a growth temperature during the formation of the gate structure and the III-V compound in the second barrier layer.

7. The method of claim 3, wherein the forming the gate structure comprises forming a gate dielectric layer on the second barrier layer, and forming a gate metal on the gate dielectric layer, wherein the ion layer is activated by a growth temperature during the formation of the III-V compound in the second barrier layer.

8. The method of claim 1, wherein the ions comprise at least one of: silicon ions, oxygen ions, germanium ions, and nitrogen ions.

9. The method of claim 2, further comprising forming a capping layer covering the first barrier layer.

10. The method of claim 9, wherein the forming the n-type doped ion layer comprises:
a) forming a patterned photoresist layer on the capping layer;
b) by using the patterned photoresist layer as a mask, etching a portion of the capping layer to expose the first barrier layer; and
c) by using the photoresist layer and the capping layer as a mask, performing ion implantation process to form the ion layer.

11. The method of claim 9, wherein after forming the n-type doped ion layer, the method further comprises forming a first dielectric layer on the capping layer.

12. A high-electron-mobility transistor (HEMT) device, the device comprising:
a) a base layer;
b) a channel layer located on the base layer;
c) a barrier layer structure located on the channel layer;
d) a source metal and a drain metal located on a first region of the barrier layer structure; and
e) a gate structure located on a second region of the barrier layer structure; wherein a surface of the first region of the barrier layer is n-type doped.

13. The device of claim 12, wherein the barrier layer structure comprises a first barrier layer covering an upper surface of the channel layer, and wherein the gate structure is located on the first barrier layer.

14. The device of claim 12, wherein the barrier layer structure comprises a first barrier layer located at least in the first region, and a second barrier layer located at least in the second region, and wherein a thickness of the second barrier layer is less than a thickness of the first barrier layer.

15. The device of claim 12, wherein the gate structure comprises a P-GaN layer and a gate metal on the P-GaN layer.

16. The device of claim 14, wherein the gate structure comprises a gate dielectric layer on the second barrier layer, and a gate metal on the gate dielectric layer.

17. The device of claim 14, further comprising a capping layer on the first barrier layer and a first dielectric layer on the capping layer.

18. A method of making a high-electron-mobility transistor (HEMT) device having a depletion-mode structure and an enhancement-mode structure, the method comprising:
a) forming a stack comprising a base layer, a channel layer, and a first barrier layer, wherein the stack comprises a first structure and a second structure;
b) implanting ions into a first region of the first barrier layer in the first structure and a second region of the first barrier layer in the second structure to form an n-type doped ion layer;
c) etching a portion of the first barrier layer in a first gate region of the first structure to expose the channel layer, wherein the first gate region is spaced apart from the first region;
d) forming a second barrier layer on the exposed channel layer, wherein the second barrier layer comprises a III-V compound;
e) forming a first gate structure on the second barrier layer;
f) forming source metals and drain metals on the first region and the second region; and
g) forming a second gate structure on a second gate region of the second structure, wherein the ion layer is activated by a growth temperature during the formation of the second barrier layer, in order to reduce ohmic contact resistance of the source metal and drain metal.

19. The method of claim 18, wherein the forming the first gate structure comprises forming P-type GaN on the second barrier layer, and forming a first gate metal on the P-type GaN.

20. The method of claim 18, wherein a thickness of the second barrier layer is less than a thickness of the first barrier layer.
